(19) United States
(12) Patent Application Publication
(10) Pub. No.: US 2024/0413653 A1
(43) Pub. Date: Dec. 12, 2024

(54) Jobsite Battery Charger Device

(71) Applicant: James Rogers, Benton, KY (US)

(72) Inventor: James Rogers, Benton, KY (US)

(21) Appl. No.: 18/207,770

(22) Filed: Jun. 9, 2023

(51) Int. Cl. H02J 7/00; H05K 5/02

(52) U.S. Cl. CPC H02J 7/0045; H02J 7/0013; H05K 5/0221; H05K 5/0247

(57) ABSTRACT

A jobsite battery charger device includes a storage box defining a storage area. A lid is hingedly coupled to the storage box for opening or closing the storage area. A plurality of battery chargers is each attached to the lid and the plurality of rechargeable batteries can be simultaneously charged in the plurality of battery chargers. In this way the plurality of battery chargers reduces clutter and tripping hazards on the jobsite. A female electrical outlet is integrated into the lid to insertably receive a male plug of a power cord. A pair of locks is each movably coupled to the storage box and each of the locks engages the lid when the locks are positioned in a locked condition to locking the lid. Conversely, each of the locks disengages the lid when the locks are positioned in an unlocked condition for unlocking the lid.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to battery charger devices and more particularly pertains to a new battery charger device for storing and simultaneously charging a plurality of rechargeable batteries. The device includes a storage box and a plurality of battery chargers attached to a lid of the storage box. The device includes a female electrical outlet integrated into the lid and a power cord attached to the storage box.

### (2) Description of Related Art Including Information Disclosed Under 37 CFR 1.97 and 1.98

The prior art relates to battery charger devices including a variety battery charging devices that includes a plurality of charging ports and a plurality of mobile charging units that each includes at least one charging bay recessed into a storage box. In no instance does the prior art disclose a storage box and a plurality of battery chargers integrated into a lid of the storage box.

### BRIEF SUMMARY OF THE INVENTION

An embodiment of the disclosure meets the needs presented above by generally comprising a storage box defining a storage area for storing a plurality of rechargeable batteries. A lid is hingedly coupled to the storage box for opening or closing the storage area. A plurality of battery chargers is each attached to the lid and the plurality of rechargeable batteries can be simultaneously charged in the plurality of battery chargers. In this way the plurality of battery chargers reduces clutter and tripping hazards on the jobsite. A female electrical outlet is integrated into the lid to insertably receive a male plug of a power cord. A pair of locks is each movably coupled to the storage box and each of the locks engages the lid when the locks are positioned in a locked condition to locking the lid. Conversely, each of the locks disengages the lid when the locks are positioned in an unlocked condition for unlocking the lid.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a top perspective view of a jobsite battery charger device according to an embodiment of the disclosure.

FIG. 2 is a left side phantom view of an embodiment of the disclosure.

FIG. 3 is a top view of an embodiment of the disclosure.

FIG. 4 is a back view of an embodiment of the disclosure.

FIG. 5 is a left view of an alternative embodiment of the disclosure.

FIG. 6 is a front view of an alternative embodiment of the disclosure.

### DETAILED DESCRIPTION OF THE INVENTION

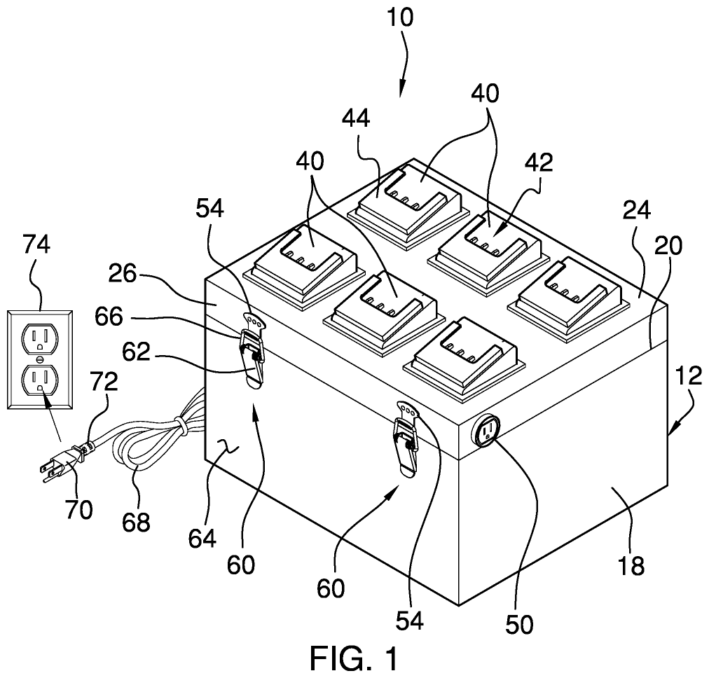

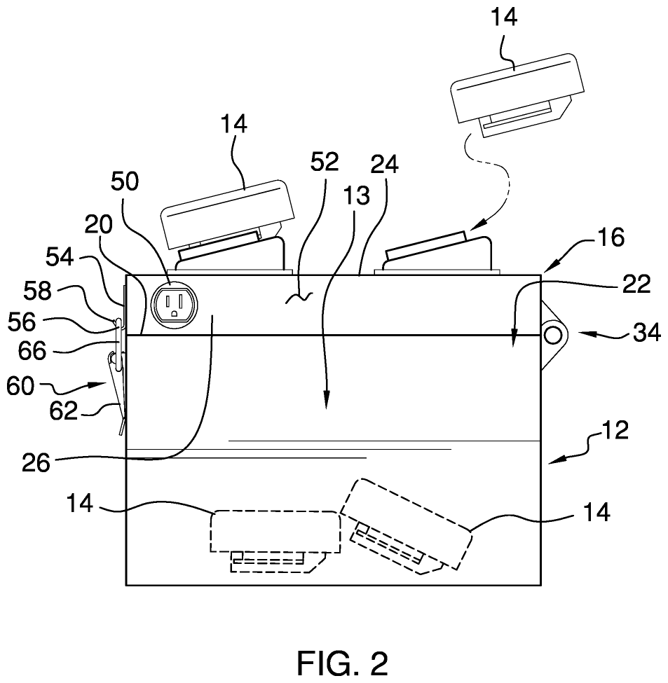

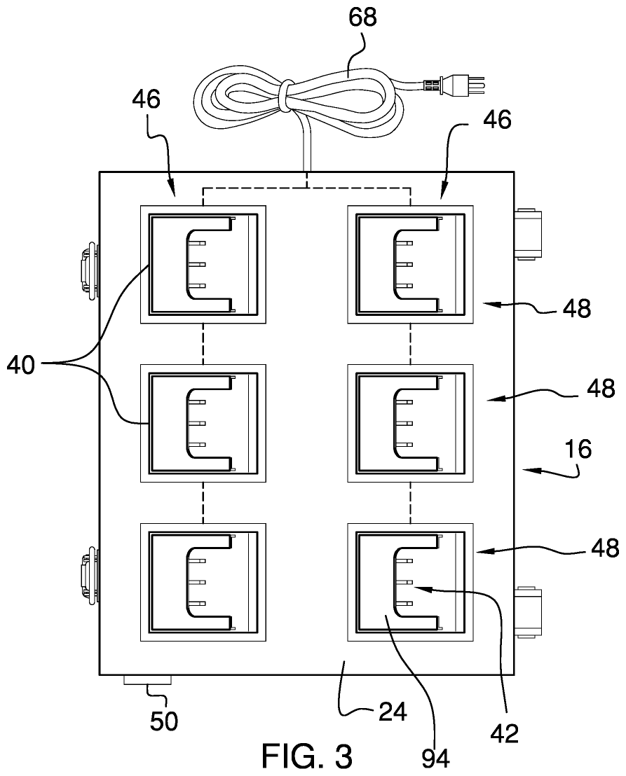

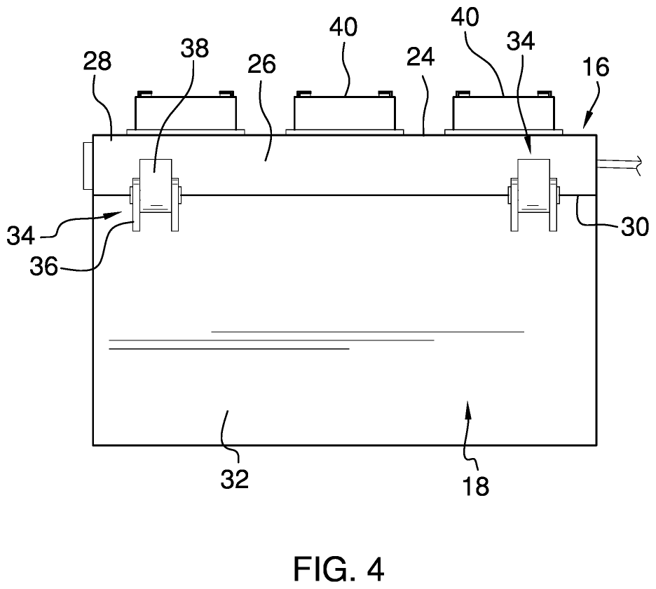

With reference now to the drawings, and in particular to FIGS. 1 through 6 thereof, a new battery charger device embodying the principles and concepts of an embodiment of the disclosure and generally designated by the reference numeral 10 will be described.

As best illustrated in FIGS. 1 through 6, the jobsite battery charger device 10 generally comprises a storage box 12 defines a storage area 13 for storing a plurality of rechargeable batteries 14 to inhibit the plurality of rechargeable batteries 14 from becoming lost on a jobsite. The rechargeable batteries 14 may be rechargeable batteries for cordless tools or other types of rechargeable batteries that would commonly be found on a construction site. Additionally, a lid 16 is hingedly coupled to the storage box 12 for opening 22 or closing the storage area 13. Each of the storage box 12 and the lid 16 are comprised of a resilient material, including but not being limited to, plastic or metal, to resist being damaged while on a construction site.

The storage box 12 has an outer wall 18 and a top edge 20 that defines an opening 22 into the storage area 13. The lid 16 has a top wall 24 and a perimeter wall 26 extending downwardly from the top wall 24 and the perimeter wall 26 has a rear side 28 and a bottom edge 30. The rear side 28 is hingedly coupled to a back side 32 of the outer wall 18 and the bottom edge 30 of the perimeter wall 26 resting on the top edge 20 of the outer wall 18 when the lid 16 is closed. A pair of hinges 34 is provided and each of the pair of hinges 34 includes a first portion 36 which pivotally engages a second portion 38. The first portion 36 of each of the pair of hinges 34 is coupled to the back side 32 of the outer wall 18 of the storage box 12 and the second portion 38 of each of the pair of hinges 34 is coupled to the rear side 28 of the perimeter wall 26 of the lid 16.

A plurality of battery chargers 40 is provided and each of the plurality of battery chargers 40 is attached to the lid 16. Each of the plurality of rechargeable batteries 14 is attachable to a respective one of the plurality of battery chargers 40 thereby facilitating the plurality of rechargeable batteries 14 to be simultaneously charged. In this way the plurality of battery chargers 40 reduce clutter and tripping hazards on the jobsite. Each of the battery chargers 40 has a charge port 42 that is integrated into an upper end 44 of the battery chargers 40. Additionally, each of the plurality of battery chargers 40 may be manufactured by a variety of well known producers of cordless tools to and each of the plurality of rechargeable batteries 14 may be compatible with the battery chargers 40.

Each of the plurality of battery chargers 40 is positioned on the top wall 24 of the lid 16 and the plurality of battery chargers 40 is arranged into a pair of rows 46 and a plurality of columns 48 on the top wall 24. A female electrical outlet 50 is integrated into the lid 16 to insertably receive a male plug of a power cord for an electronic device for suppling electrical power to the power cord. The female electrical outlet 50 is integrated into an outwardly facing surface 52 of the perimeter wall 26 of the lid 16. The female electrical outlet 50 may comprise a three prong electrical outlet or the like.

A pair of hooks 54 is each attached to the outwardly facing surface 52 of the perimeter wall 26 of the lid 16. Each of the hooks 54 has a curve 56 which directs a bottom end 58 of the hooks 54 upwardly. A pair of locks 60 is each movably coupled to the storage box 12 and each of the locks 60 engages the lid 16 when the locks 60 are positioned in a locked condition to lock the lid 16. Conversely, each of the locks 60 disengages the lid 16 when the locks 60 are positioned in an unlocked condition for unlocking the lid 16. Each of the locks 60 includes a lever 62 that is pivotally disposed on an outwardly facing surface 64 of the outer wall 18 of the box and each of the locks 60 includes a loop 66 that is pivotally attached to the lever 62. The loop 66 associated with each of the locks 60 rests in the curve 56 of a respective one of the hooks 54 when the locks 60 are in the closed condition. Conversely, the loop 66 associated with each of the locks 60 is displaced from the respective hook 54 when the locks 60 are in the unlocked condition.

A power cord 68 is coupled to and extends away from the perimeter wall 26 of the lid 16. The power cord 68 is electrically coupled to each of the plurality of battery chargers 40 and the power cord 68 is electrically coupled to the female electrical outlet 50. The power cord 68 has a male plug 70 that is electrically coupled to a distal end 72 of the power cord 68. In this way the male plug 70 on the distal end 72 can be plugged into a power source 74 comprising a female electrical outlet.

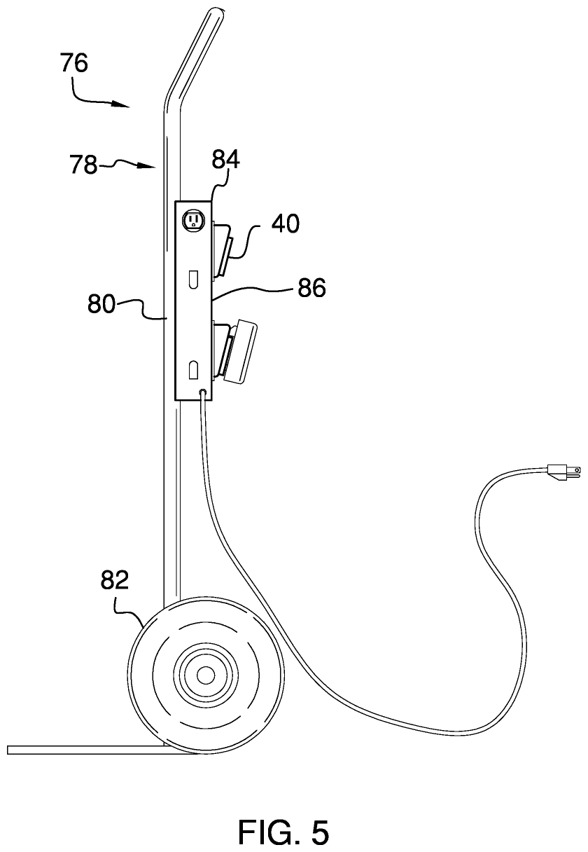

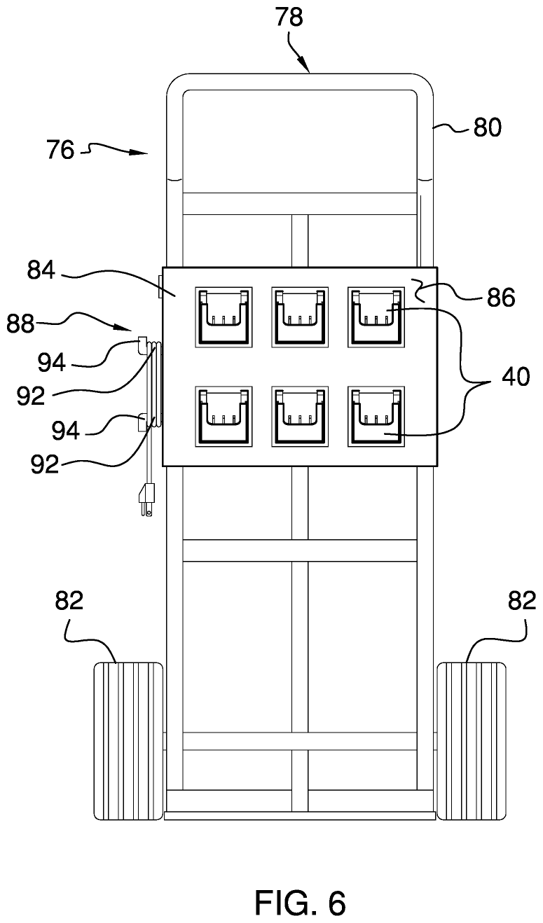

In an alternative embodiment 76 as shown in FIGS. 5 and 6, a hand truck 78 is included which has a frame 80 and a pair of wheels 82 rotatably coupled to the frame 80. A panel 84 is attached to the frame 80 and each of the plurality of battery chargers 40 is coupled to a forward surface 86 of the panel 84. The panel 84 has a cord holder 88 that is attached to a lateral surface 90 of the panel 84 and the cord holder 88 includes a pair of legs 92 extending away from the lateral surface 90 and a pair of feet 94 perpendicularly oriented with a respective leg 92. The power cord 68 extends away from the lateral surface 90 and the power cord 68 is wrapped around pair of legs 92 for storage.

In use, the rechargeable batteries 14 are stored in the storage box 12 when the rechargeable batteries 14 are not being employed. The power cord 68 is plugged into the power source 74 and each of the rechargeable batteries 14 is charged either individually as needed or simultaneously. In this way the plurality of batteries 14 can be stored and charged with a single power cord rather than being required to employ multiple individual battery chargers each with their own power cord. Thus, the jobsite has fewer tripping hazards and is more organized thereby enhancing safety and efficiency of workers on the jobsite.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A jobsite battery charger device for storing and simultaneously charging a plurality of rechargeable batteries, said device comprising:
a storage box defining a storage area for storing a plurality of rechargeable batteries wherein said storage box is configured to inhibit said plurality of rechargeable batteries from becoming lost on a jobsite, said storage box having a lid being hingedly coupled to said storage box for opening or closing said storage area;
a plurality of battery chargers, each of said plurality of battery chargers being attached to said lid, each of said plurality of rechargeable batteries being attachable to a respective one of said plurality of battery chargers thereby facilitating said plurality of rechargeable batteries to be simultaneously charged wherein said plurality of battery chargers is configured to reduce clutter and tripping hazards on the jobsite;
a female electrical outlet being integrated into said lid wherein said female electrical outlet is configured to insertably receive a male plug of a power cord for suppling electrical power to the power cord; and
a pair of locks, each of said locks being movably coupled to said storage box, each of said locks engaging said lid when said locks are positioned in a locked condition to locking said lid, each of said locks disengaging said lid when said locks are positioned in an unlocked condition for unlocking said lid.

2. The assembly according to claim 1, wherein:
said storage box has an outer wall and a top edge defining an opening into said storage area;
said lid has a top wall and a perimeter wall extending downwardly from said top wall, said perimeter wall having a rear side and a bottom edge, said rear side being hingedly coupled to a back side of said outer wall, said bottom edge of said perimeter wall resting on said top edge of said outer wall when said lid is closed;
a pair of hinges, each of said hinges including a first portion pivotally engaging a second portion, said first portion of each of said pair of hinges being coupled to said back side of said outer wall of said storage box, said second portion of each of said pair of hinges being coupled to said rear side of said perimeter wall of said lid; and
each of said battery chargers having a charge port being integrated into an upper end of said battery chargers, each of said plurality of battery chargers being positioned on said top wall of said lid, said plurality of battery chargers being arranged into a pair of rows and a plurality of columns on said top wall.

3. The assembly according to claim 2, wherein said female electrical outlet is integrated into an outwardly facing surface of said perimeter wall of said lid.

4. The assembly according to claim 2, further comprising a pair of hooks, each of said hooks being attached to said outwardly facing surface of said perimeter wall of said lid, each of said hooks having a curve directing a bottom end of said hooks upwardly.

5. The assembly according to claim 4, wherein each of said locks includes a lever being pivotally disposed on an outwardly facing surface of said outer wall of said box, each of said locks including a loop being pivotally attached to said lever, said loop associated with each of said locks resting in said curve of a respective one of said hooks when said locks are in said closed condition, said loop associated with each of said locks being displaced from said respective hook when said locks are in said unlocked condition.

6. The assembly according to claim 1, further comprising a power cord being coupled to and extending away from said lid, said power cord being electrically coupled to each of said plurality of battery chargers, said power cord being electrically coupled to said female electrical outlet, said power cord having a male plug being electrically coupled to a distal end of said power cord wherein said male plug on said distal end is configured to be plugged into a power source comprising a female electrical outlet.

7. A jobsite battery charger device for storing and simultaneously charging a plurality of rechargeable batteries, said device comprising:
a storage box defining a storage area for storing a plurality of rechargeable batteries wherein said storage box is configured to inhibit said plurality of rechargeable batteries from becoming lost on a jobsite, said storage box having a lid being hingedly coupled to said storage box for opening or closing said storage area, said storage box having an outer wall and a top edge defining an opening into said storage area, said lid having a top wall and a perimeter wall extending downwardly from said top wall, said perimeter wall having a rear side and a bottom edge, said rear side being hingedly coupled to a back side of said outer wall, said bottom edge of said perimeter wall resting on said top edge of said outer wall when said lid is closed;
a pair of hinges, each of said hinges including a first portion pivotally engaging a second portion, said first portion of each of said pair of hinges being coupled to said back side of said outer wall of said storage box, said second portion of each of said pair of hinges being coupled to said rear side of said perimeter wall of said lid;
a plurality of battery chargers, each of said plurality of battery chargers being attached to said lid, each of said plurality of rechargeable batteries being attachable to a respective one of said plurality of battery chargers thereby facilitating said plurality of rechargeable batteries to be simultaneously charged wherein said plurality of battery chargers is configured to reduce clutter and tripping hazards on the jobsite, each of said battery chargers having a charge port being integrated into an upper end of said battery chargers, each of said plurality of battery chargers being positioned on said top wall of said lid, said plurality of battery chargers being arranged into a pair of rows and a plurality of columns on said top wall;
a female electrical outlet being integrated into said lid wherein said female electrical outlet is configured to insertably receive a male plug of a power cord for suppling electrical power to the power cord, said female electrical outlet being integrated into an outwardly facing surface of said perimeter wall of said lid;
a pair of hooks, each of said hooks being attached to said outwardly facing surface of said perimeter wall of said lid, each of said hooks having a curve directing a bottom end of said hooks upwardly;
a pair of locks, each of said locks being movably coupled to said storage box, each of said locks engaging said lid when said locks are positioned in a locked condition to locking said lid, each of said locks disengaging said lid when said locks are positioned in an unlocked condition for unlocking said lid, each of said locks including a lever being pivotally disposed on an outwardly facing surface of said outer wall of said box, each of said locks including a loop being pivotally attached to said lever, said loop associated with each of said locks resting in said curve of a respective one of said hooks when said locks are in said closed condition, said loop associated with each of said locks being displaced from said respective hook when said locks are in said unlocked condition; and
a power cord being coupled to and extending away from said lid, said power cord being electrically coupled to each of said plurality of battery chargers, said power cord being electrically coupled to said female electrical outlet, said power cord having a male plug being electrically coupled to a distal end of said power cord wherein said male plug on said distal end is configured to be plugged into a power source comprising a female electrical outlet.

8. The assembly according to claim 7, further comprising:
a hand truck having a frame and a pair of wheels rotatably coupled to said frame; and
a panel being attached to said frame, each of said plurality of battery chargers being coupled to a forward surface of said panel, said panel having a cord holder attached to a lateral surface of said panel, said cord holder including a pair of legs extending away from said lateral surface and a pair of feet perpendicularly oriented with a respective leg, said power cord extending away from said lateral surface, said power cord being wrapped around pair of legs for storage.
